(19) United States
(12) Patent Application Publication
(10) Pub. No.: US 2016/0334682 A1
(43) Pub. Date: Nov. 17, 2016

(54) Color Filter on Array Substrate and Method for Manufacturing the same, as well as Display Device

(71) Applicant: BOE TECHNOLOGY GROUP CO., LTD., Beijing (CN)

(72) Inventors: Feng Zhang, Beijing (CN); Zhanfeng Cao, Beijing (CN); Qi Yao, Beijing (CN)

(21) Appl. No.: 14/762,197

(22) PCT Filed: Mar. 16, 2015
(86) PCT No.: PCT/CN2015/074283

§ 371 Date: Jul. 20, 2015

(30) Foreign Application Priority Data
Oct. 31, 2014 (CN) 201410602745.5

(51) Int. Cl. G02F 1/1362; H01L 27/12; H01L 29/786; G02F 1/1333

(52) U.S. Cl. CPC G02F 1/136209; G02F 1/136286; G02F 1/133308; H01L 27/1225; H01L 29/7869; H01L 27/124; H01L 27/1262; G02F 2001/13606

(57) ABSTRACT

The color filter on array substrate comprises a gate line, a data line, a common electrode layer and a black matrix, wherein: the black matrix is positioned between the gate line and the common electrode layer and/or the data line and the common electrode layer; and the material of the black matrix is a metal material. The present disclosure is applied in the technology of manufacturing display means.

### CROSS-REFERENCE TO RELATED APPLICATIONS

The present disclosure claims the benefit of Chinese Patent Application No. 201410602745.5, filed on Oct. 31, 2014, the entire disclosure of which is incorporated herein by reference.

### TECHNICAL FIELD

The disclosure relates to the field of display technology, and more particularly to a color filter on array substrate and method for manufacturing the same, as well as a display device thereof.

### BACKGROUND ART

Display means, such as a liquid crystal display (LCD) and an organic electroluminescent device (OLED), are necessities in human lives. With the improvement of people's needs, a technology of integrating a color filter with an array substrate, namely Color Filter on Array (COA), came into being so as to enhance the display quality of the display device, and avoid the issue of aperture ratio and light leakage of the display device as a result of a deviation when box aligning the array substrate and the color film substrate. The COA technology is to arrange a black matrix and a color filter on an array substrate.

The existing black matrix is usually made of resin encapsulating carbon black particles that have a certain degree of conductivity and a greater dielectric constant. The black matrix in the existing COA substrate is usually positioned between a gate line and a common electrode and/or a data line and a common electrode, such that a great parasitic capacitance may occur between the common electrode and the gate line and/or the common electrode and the data line, thereby resulting in severe signal delay and lowering the screen display quality of the display means.

### SUMMARY OF THE DISCLOSURE

The present disclosure provides a COA substrate and a method for manufacturing the same, as well as a display device, which solves the problem of a greater parasitic capacitance generated between the common electrode and the gate line and/or the common electrode and the data line in the prior-art technical solutions, avoids signal delay, guarantees normal signal transmission and improves screen display quality of the display means.

To this end, an embodiment of the present disclosure adopts the following technical solution:

In the first aspect, a COA substrate is provided, which comprises a gate line, a data line, a common electrode layer and a black matrix, wherein:

the black matrix is positioned between the gate line and the common electrode layer and/or the data line and the common electrode layer;

the material of the black matrix is a metal material.

Alternatively, the black matrix is arranged at a side adjacent to the common electrode layer.

Alternatively, the COA substrate further comprises a flat layer and a color filter, wherein:

the color filter is formed on the black matrix and covers the substrate, and the color filter is covered by the flat layer.

Alternatively, the materials of the black matrix include at least one of the group consisting of molybdenum, chromium, aluminum, titanium and copper or at least one of the group consisting of metal oxides and metal nitrides corresponding to molybdenum, chromium, aluminum, titanium and copper.

Alternatively, the black matrix has a thickness ranging from 0.2 to 0.4 μm.

In the second aspect, a COA substrate is provided, which comprises a common electrode layer and a black matrix arranged on the substrate, wherein:

the black matrix is arranged on the common electrode layer.

Alternatively, the material of the black matrix is a metal material.

Alternatively, the materials of the black matrix include at least one of the group consisting of molybdenum, chromium, aluminum, titanium and copper or at least one of the group consisting of metal oxides and metal nitrides corresponding to molybdenum, chromium, aluminum, titanium and copper.

Alternatively, the black matrix has a thickness ranging from 0.2 to 0.4 μm.

In the third aspect, a method for manufacturing a COA substrate is provided, which comprises the step of forming a gate line, a data line and a common electrode layer on the substrate, and further:

forming a black matrix of a metal material between the gate line and the common electrode layer and/or the data line and the common electrode layer.

Alternatively, the method further comprises the steps of:

forming a color filter on the substrate; and

forming a flat layer that covers the color filter on the color filter.

Alternatively, the step of forming a black matrix of a metal material between the gate line and the common electrode layer and/or the data line and the common electrode layer comprises the steps of:

forming a layer of metal film from the metal material on the gate line and the data line;

treating the metal film by a patterning process to form the black matrix;

forming the common electrode layer, which comprises the step of:

forming the common electrode layer above the black matrix in a position adjacent to the black matrix.

Alternatively, the black matrix is formed using an array substrate through a patterning process with an exposure device.

Alternatively, the materials of the black matrix include at least one of the group consisting of molybdenum, chromium, aluminum, titanium and copper or at least one of the group consisting of metal oxides and metal nitrides corresponding to molybdenum, chromium, aluminum, titanium and copper.

Alternatively, the black matrix has a thickness ranging from 0.2 to 0.4 μm.

In the fourth aspect, a method for manufacturing a COA substrate is provided, which comprises the step of forming a common electrode layer on the substrate, and further:

forming a black matrix on the common electrode layer.

Alternatively, the step of forming a black matrix on the common electrode layer comprises the steps of:

forming a layer of metal film from the metal material on the common electrode layer; and

forming the black matrix by treating the metal film using the array substrate through a patterning process with an exposure device.

Alternatively, the materials of the black matrix include at least one of the group consisting of molybdenum, chromium, aluminum, titanium and copper or at least one of the group consisting of metal oxides and metal nitrides corresponding to molybdenum, chromium, aluminum, titanium and copper.

Alternatively, the black matrix has a thickness ranging from 0.2 to 0.4 μm.

In the fifth aspect, a display device is provided, which comprises any COA substrate as recited in the first aspect;

or any COA substrate as recited in the second aspect.

As to the COA substrate and the method for manufacturing the same, as well as the display device according to the present disclosure, the metal material is used to form the black matrix in the COA substrate, and the black matrix made of the metal material replaces the black matrix made of carbon black particles in the prior-art technical solutions, such that it is effective to avoid the augmentation of the parasitic capacitance between the common electrode and the gate line and/or the common electrode and the data line due to the presence of the black matrix made of carbon black particles, which solves the problem of a greater parasitic capacitance generated between the common electrode and the gate line and/or the common electrode and the data line in the prior-art technical solutions, avoids signal delay, guarantees normal signal transmission and improves screen display quality of the display means.

### BRIEF DESCRIPTION OF DRAWINGS

To explain the embodiments of the present disclosure or technical solutions in the prior art more clearly, the drawings used in the description of the embodiments or the prior art will be briefly introduced as follows. Apparently, the drawings as described below are only for illustrating some embodiments of the present disclosure. Those skilled in the art can obtain other drawings according to these drawings without making any inventive effort.

FIG. 1 is a structural schematic view of a COA substrate according to one embodiment of the present disclosure;

FIG. 2 is a structural schematic view of another COA substrate according to another embodiment of the present disclosure;

FIG. 3 is a structural schematic view of a further COA substrate according to a further embodiment of the present disclosure;

FIG. 4 is a flow-chart schematic view of a method for manufacturing a COA substrate according to a yet further embodiment of the present disclosure;

FIG. 5 is a flow-chart schematic view of a method for manufacturing another COA substrate according to one embodiment of the present disclosure;

FIG. 6 is a flow-chart schematic view of a method for manufacturing a further COA substrate according to another embodiment of the present disclosure;

FIG. 7 is a flow-chart schematic view of a method for manufacturing a COA substrate according to a further embodiment of the present disclosure; and

FIG. 8 is a flow-chart schematic view of a method for manufacturing another COA substrate according to a yet further embodiment of the present disclosure.

Reference signs: 1—substrate; 2—gate; 3—gate insulating layer; 4—active layer; 5—source; 6—drain; 7—first passivation layer; 8—black matrix; 9—common electrode layer; 10—flat layer; 11—color filter; 12—second passivation layer; 13—pixel electrode layer.

### DETAILED DESCRIPTION OF THE DISCLOSURE

The technical solutions of the embodiments of the present disclosure will be further described clearly and completely with reference to the drawings thereof. It is apparent that the embodiments described herein are only a portion of, not all of, the embodiments of the present disclosure. All the other embodiments obtained by those skilled in the art based on the embodiments of the present disclosure without making any inventive effort fall within the protection scope of the present disclosure.

An embodiment of the present disclosure provides a COA substrate. With reference to FIG. 1, the COA substrate comprises a substrate 1, a gate 2, a gate line (not shown), a gate insulating layer 3, an active layer 4, a source 5, a drain 6, a data line (not shown), a first passivation layer 7, a black matrix 8 and a common electrode layer 9, wherein:

the black matrix 8 is positioned between the gate line and the common electrode layer 9 and/or the data line and the common electrode layer 9.

The material of the black matrix 8 is a metal material.

To be specific, the black matrix of the present embodiment is made of a metal material, preferably a metal material having relatively low reflectivity. Compared with the carbon black particles in the prior-art black matrix, the dielectric constant of the metal material is much smaller than that of the carbon black particles, which greatly reduces the parasitic capacitance between the data line and the common electrode layer and/or the gate line and the common electrode layer in the COA substrate.

Wherein the substrate can be a glass substrate or quartz substrate; the gate, the source and the drain can be formed from a metal material; the gate insulating layer can be formed of silicon nitride, silicon oxide, or silicon oxynitride; the active layer can be formed of a metal oxide semiconductor material; the first passivation layer can be made of silicon nitride or transparent organic resin. The common electrode layer can be made of indium tin oxide (ITO) or indium-doped zinc oxide (IZO).

As to the COA substrate according to the embodiment of the present disclosure, the metal material is used to form the black matrix in the COA substrate, and the black matrix made of the metal material replaces the black matrix made of carbon black particles in the prior-art technical solutions, such that it is effective to avoid the augmentation of the parasitic capacitance between the common electrode and the gate line and/or the common electrode and the data line due to the presence of the black matrix made of carbon black particles, which solves the problem of a greater parasitic capacitance generated between the common electrode and the gate line and/or the common electrode and the data line in the prior-art technical solutions, avoids signal delay, guarantees normal signal transmission and improves screen display quality of the display means.

As shown in FIG. 1, the COA substrate further comprises a flat layer 10 and a color filter 11, wherein:

the color filter 11 is formed on the black matrix 8 and covers the substrate 1, and the color filter 11 is covered by the flat layer 10.

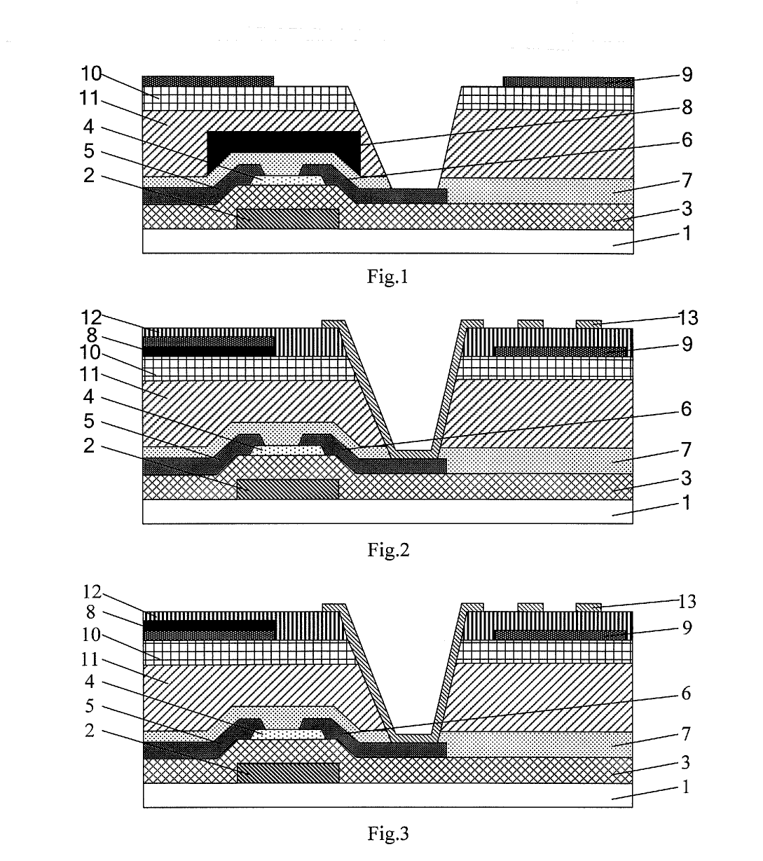

Further, with reference to FIG. 2, the black matrix 8 of the COA substrate is arranged at a side adjacent to the common electrode layer 9.

In the present embodiment, the black matrix is arranged below the common electrode layer and electrically connected therewith. Since the black matrix is made of a metal material that allows for conductivity with a lower dielectric constant, the uniformity of the common electrode layer can be improved, which further increases screen display quality. Meanwhile, compared with the black matrix made of carbon black particles, the black matrix made of the metal material can, in practical applications, guarantee the shading effect of the black matrix, minimize the width of the black matrix and enhance the aperture ratio of the display panel due to the characteristics of the metal material per se.

The materials of the black matrix include at least one of the group consisting of molybdenum, chromium, aluminum, titanium and copper or at least one of the group consisting of metal oxides and metal nitrides corresponding to molybdenum, chromium, aluminum, titanium and copper.

The black matrix has a thickness ranging from 0.2 to 0.4 μm.

To be specific, the present embodiment preferably uses at least one of the group consisting of molybdenum, chromium, aluminum, titanium and copper that have a low reflectivity or an alloy containing at least one of the above metals or metal oxides and nitrides corresponding to any one of the above metals as the material of the black matrix, which reduces the influences on other layer structures in the COA substrate by an overlarge reflectivity of the black matrix and meanwhile guarantees the shading effect of the black matrix. The black matrix has a thickness ranging from 0.2 to 0.4 μm, which ensures that the formed black matrix has a good visible light absorption effect to achieve the light-absorbing effect of the black matrix.

Since the black matrix of the present embodiment is made of a metal material, it can be made by an exposure apparatus (namely, an exposure machine used for an array substrate) and an etching apparatus which forms the layer structure of the COA substrate. Compared with a color film exposure machine used for forming the black matrix in the prior art, the exposure machine used for the array substrate has a higher alignment precision and resolution, so as to further enhance the precision of aligning the gate line with the black matrix and the data line with the black matrix, achieve the shading effect in the event that the black matrix has a small width, and maximally improve the aperture ratio of the display panel.

What needs to be explained is that as shown in FIG. 2, the COA substrate further comprises the second passivation layer 12 and the pixel electrode layer 13, wherein the second passivation layer can be formed of silicon nitride or transparent organic resin; and the pixel electrode layer can be formed of ITO or IZO.

As to the COA substrate according to the embodiment of the present disclosure, the metal material is used to form the black matrix in the COA substrate, and the black matrix made of the metal material replaces the black matrix made of carbon black particles in the prior-art technical solutions, such that it is effective to avoid the augmentation of the parasitic capacitance between the common electrode and the gate line and/or the common electrode and the data line due to the presence of the black matrix made of carbon black particles, which solves the problem of a greater parasitic capacitance generated between the common electrode and the gate line and/or the common electrode and the data line in the prior-art technical solutions, avoids signal delay, guarantees normal signal transmission and improves screen display quality of the display means.

An embodiment of the present disclosure provides a COA substrate. With reference to FIG. 3, the COA substrate comprises a substrate 1, a gate 2, a gate insulating layer 3, an active layer 4, a source 5, a drain 6, a first passivation layer 7, a black matrix 8 and a common electrode layer 9, wherein:

the black matrix 8 is positioned on the common electrode layer 9.

To be specific, in an embodiment of the present disclosure, the black matrix is arranged on the common electrode layer, such that the black matrix will not occur in a position between the gate line and the common electrode layer and between the data line and the common electrode layer, which, in comparison with the prior art solutions, greatly reduces the dielectric constant between the gate line and the common electrode layer and/or the data line and the common electrode layer, thereby decreasing the parasitic capacitance between the gate line and the common electrode layer and/or the data line and the common electrode layer.

Wherein the material of the black matrix 8 is a metal material.

In an embodiment of the present disclosure, the black matrix is made of a metal material. Since the metal material allows for conductivity with a lower dielectric constant, electric connection between the black matrix with the common electrode layer improves the uniformity of the common electrode layer and further increases screen display quality. Meanwhile, compared with the black matrix made of carbon black particles, the black matrix made of the metal material can, in practical applications, guarantee the shading effect of the black matrix, minimize the width of the black matrix and enhance the aperture ratio of the display panel due to the characteristics of the metal material.

To be specific, the materials of the black matrix can include at least one of the group consisting of molybdenum, chromium, aluminum, titanium and copper or at least one of the group consisting of metal oxides and metal nitrides corresponding to molybdenum, chromium, aluminum, titanium and copper.

The black matrix has a thickness ranging from 0.2 to 0.4 μm.

To be specific, the embodiment of the present disclosure preferably uses at least one of the group consisting of molybdenum, chromium, aluminum, titanium and copper that have a low reflectivity or an alloy containing at least one of the above metals or metal oxides and nitrides corresponding to any one of the above metals as the material of the black matrix, which reduces the influences on the structures of other layers in the COA substrate by an overlarge reflectivity of the black matrix and meanwhile guarantees the shading effect of the black matrix. The black matrix has a thickness ranging from 0.2 to 0.4 μm, which ensures that the formed black matrix has a good visible light absorption effect to achieve the light-absorbing effect of the black matrix.

What needs to be explained is that as shown in FIG. 3, the COA substrate further comprises the flat layer 10, the color filter 11, the second passivation layer 12 and the pixel electrode layer 13.

Wherein the substrate can be a glass substrate or quartz substrate; the gate, the source and the drain can be formed from a metal material; the gate insulating layer can be formed of silicon nitride, silicon oxide, or silicon oxynitride; the active layer can be formed of a metal oxide semiconductor material; the first and second passivation layers can be made of silicon nitride or transparent organic resin. The common electrode layer and the pixel electrode layer can be made of ITO or IZO.

In the COA substrate according to an embodiment of the present disclosure, the black matrix in the COA substrate is arranged on the common electrode layer, such that the black matrix will not occur in a position between the common electrode and the gate line and/or between the common electrode and the data line, which effectively avoids the augmentation of the parasitic capacitance between the common electrode and the gate line and/or the common electrode and the data line due to the presence of the black matrix made of carbon black particles, which solves the problem of a greater parasitic capacitance generated between the common electrode and the gate line and/or the common electrode and the data line due to the presence of the black matrix, solves the problem of a greater parasitic capacitance generated between the common electrode and the gate line and/or the common electrode and the data line in the prior-art technical solutions, avoids signal delay, guarantees normal signal transmission and improves screen display quality of the display means.

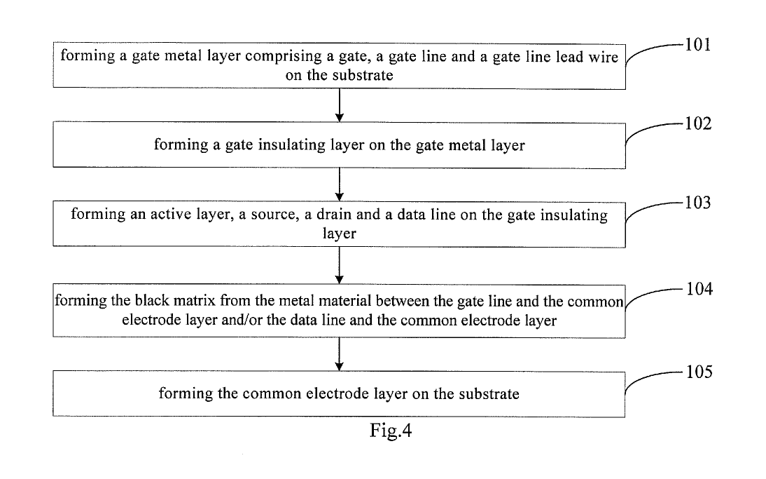

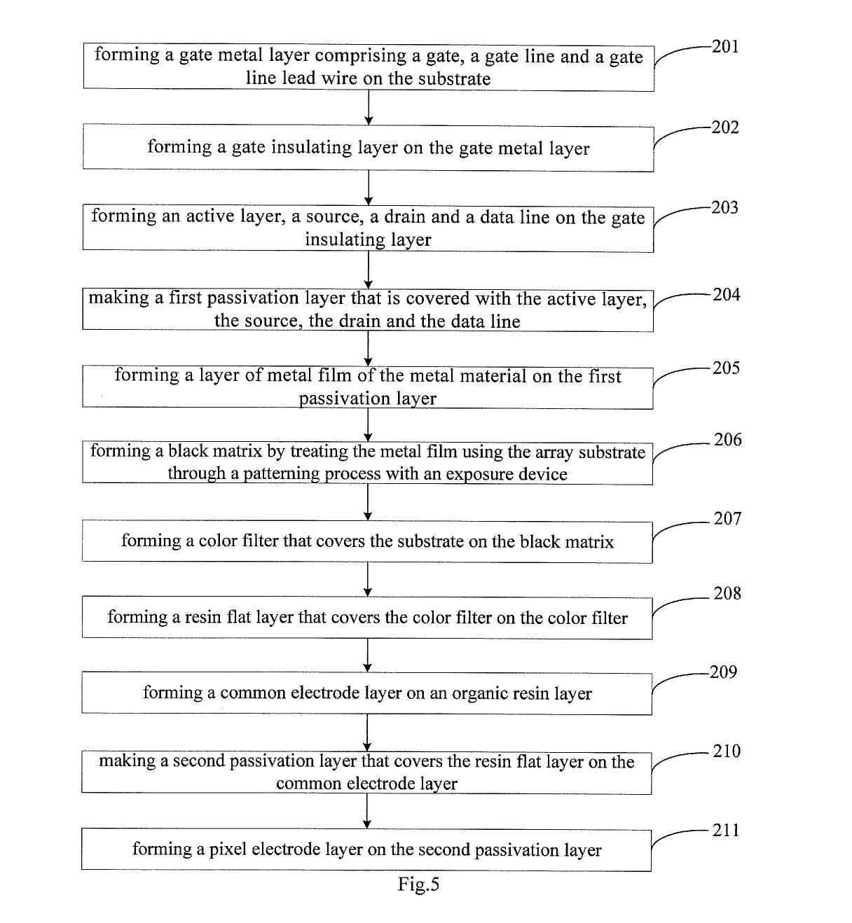

The embodiment of the present disclosure provides a method for manufacturing a COA substrate. With reference to FIG. 4, the method comprises the following steps:

101. forming a gate metal layer comprising a gate, a gate line and a gate line lead wire on the substrate.

To be specific, a layer of metal film with a thickness ranging from 1000 Å to 7000 Å is deposited on the substrate, such as a glass substrate or a quartz substrate by means of magnetron sputtering. The metal film is usually made of a metal selected from the group consisting of molybdenum, aluminium, aluminium-nickel alloy, molybdenum-tungsten alloy, chromium or copper, or a combination of films made of the above materials. Then, the gate metal layer is formed on a certain area of the substrate by a mask plate using a patterning process such as exposure, developing, etching and peeling.

102. forming a gate insulating layer on the gate metal layer.

To be specific, a film of the gate insulating layer with a thickness ranging from 1000 Å to 6000 Å is deposited on the glass substrate by means of chemical vapor deposition or magnetron sputtering. The film of the gate insulating layer is usually made of silicon nitride, but silicon oxide or silicon oxynitride can also be used.

103. forming the active layer, the source, the drain and the data line on the gate insulating layer.

To be specific, a metal oxide semiconductor film is deposited on the gate insulating layer by means of chemical vapor deposition, then the metal oxide semiconductor film is treated by the patterning process to form the active layer, i.e., after photoresist is applied, the substrate is exposed, developed and etched using a typical mask plate to form the active layer.

Further, similar to the method for manufacturing the gate line, a metal film with a thickness ranging from 1000 Å to 7000 Å, which is similar to a gate metal, is deposited on the substrate, on the certain area of which the source, the drain and the data line are formed by means of a patterning process.

104. forming the black matrix from the metal material between the gate line and the common electrode layer and/or the data line and the common electrode layer.

105. forming the common electrode layer on the substrate.

To be specific, a layer of ITO or IZO with a thickness ranging from 300 Å to 500 Å is deposited by means of magnetron sputtering and then forms the common electrode layer after exposure, developing and etching.

As to the COA substrate according to the embodiment of the present disclosure, the metal material is used to form the black matrix in the COA substrate, and the black matrix made of the metal material replaces the black matrix made of carbon black particles in the prior-art technical solutions, such that it is effective to avoid the augmentation of the parasitic capacitance between the common electrode and the gate line and/or the common electrode and the data line due to the presence of the black matrix made of carbon black particles, which solves the problem of a greater parasitic capacitance generated between the common electrode and the gate line and/or the common electrode and the data line in the prior-art technical solutions, avoids signal delay, guarantees normal signal transmission and improves screen display quality of the display means.

The embodiment of the present disclosure provides a method for manufacturing a COA substrate. With reference to FIG. 5, the method comprises the following steps:

201. forming a gate metal layer comprising a gate, a gate line and a gate line lead wire on the substrate.

To be specific, a layer of metal film with a thickness ranging from 1000 Å to 7000 Å is deposited on the substrate, such as a glass substrate or a quartz substrate by means of magnetron sputtering. The metal film is usually made of a metal selected from the group consisting of molybdenum, aluminium, aluminium-nickel alloy, molybdenum-tungsten alloy, chromium or copper, or a combination of films made of the above materials. Then, the gate metal layer is formed on a certain area of the substrate by a mask plate using a patterning process such as exposure, developing, etching and peeling.

202. forming a gate insulating layer on the gate metal layer.

To be specific, a film of the gate insulating layer with a thickness ranging from 1000 Å to 6000 Å is deposited on the glass substrate by means of chemical vapor deposition or magnetron sputtering. The film of the gate insulating layer is usually made of silicon nitride, but silicon oxide or silicon oxynitride can also be used.

203. forming the active layer, the source, the drain and the data line on the gate insulating layer.

To be specific, a metal oxide semiconductor film is deposited on the gate insulating layer by means of chemical vapor deposition, then the metal oxide semiconductor film is treated by the patterning process to form the active layer, i.e., after photoresist is applied, the substrate is exposed, developed and etched using a typical mask plate to form the active layer.

Further, similar to the method for manufacturing the gate line, a metal film with a thickness ranging from 1000 Å to 7000 Å, which is similar to a gate metal, is deposited on the substrate, on the certain area of which the source, the drain and the data line are formed by means of a patterning process.

204. making the first passivation layer that is covered with the active layer, the source, the drain and the data line.

To be specific, similar to the method for making the gate insulating layer and the active layer, the first passivation layer with a thickness of 1000 Å to 6000 Å is applied over the substrate, and the material thereof is usually silicon nitride or transparent organic resin.

205. forming the layer of metal film by a metal material on the first passivation layer.

206. treating the metal film by the array substrate through the patterning process with an exposure device so as to form the black matrix.

To be specific, the black matrix with a thickness ranging from 2000 Å to 6000 Å is formed by treating the metal film using the exposure apparatus (namely, the exposure machine for the array substrate) and the etching apparatus that form the layer structure, such as the source and the drain, in the COA substrate. The material of the black matrix can be selected from at least one of the group consisting of molybdenum, chromium, aluminum, titanium and copper or an alloy containing at least one of the above metals or metal oxides and nitrides corresponding to any one of the above metals.

207. forming the color filter that covers the substrate on the black matrix.

208. forming the flat layer that covers the color filter on the color filter.

209. forming the common electrode layer on the organic resin layer.

To be specific, a layer of ITO or IZO with a thickness ranging from 300 Å to 500 Å is deposited by means of magnetron sputtering and then forms the common electrode layer after exposure, developing and etching.

210. making the second passivation layer that covers the flat layer on the common electrode layer.

To be specific, similar to the method for making the gate insulating layer and the active layer, the passivation layer is applied over the substrate, and the material thereof is usually silicon nitride or transparent organic resin.

211. forming the pixel electrode layer on the second passivation layer.

The ITO or IZO is deposited on the second passivation layer by means of magnetron sputtering and then forms the common electrode layer after exposure, developing and etching.

As to the method for manufacturing the COA substrate according to the embodiment of the present disclosure, the metal material is used to form the black matrix in the COA substrate, and the black matrix made of the metal material replaces the black matrix made of carbon black particles in the prior-art technical solutions, such that it is effective to avoid the augmentation of the parasitic capacitance between the common electrode and the gate line and/or the common electrode and the data line due to the presence of the black matrix made of carbon black particles, which solves the problem of a greater parasitic capacitance generated between the common electrode and the gate line and/or the common electrode and the data line in the prior-art technical solutions, avoids signal delay, guarantees normal signal transmission and improves screen display quality of the display means.

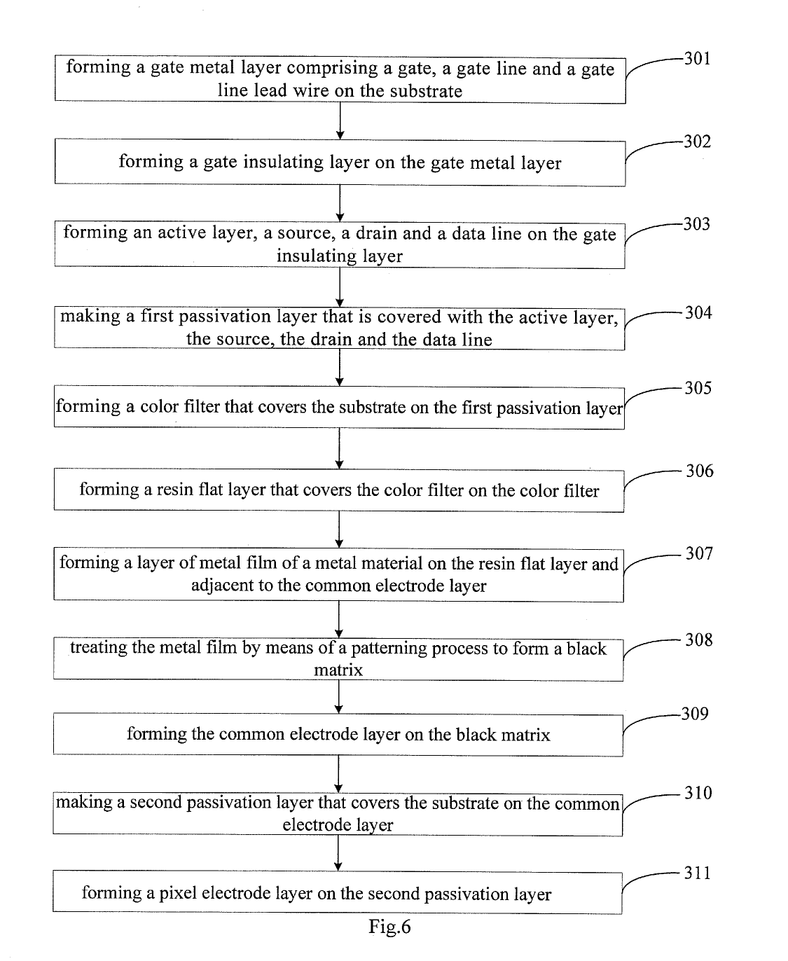

The embodiment of the present disclosure provides a method for manufacturing a COA substrate. With reference to FIG. 6, the method comprises the following steps:

301. forming a gate metal layer comprising a gate, a gate line and a gate line lead wire on the substrate.

302. forming a gate insulating layer on the gate metal layer.

303. forming an active layer, a source, a drain and a data line on the gate insulating layer.

304. making a first passivation layer that is covered with the active layer, the source, the drain and the data line.

305. forming a color filter that covers the substrate on a first passivation layer.

306. forming a flat layer that covers the color filter on the color filter.

307. forming a layer of metal film from a metal material on the flat layer and adjacent to the common electrode layer.

308. treating the metal film by means of patterning process to form a black matrix.

Wherein, the black matrix can be formed using an array substrate through the patterning process with an exposure apparatus.

To be specific, the exposure apparatus for the array substrate can be identical with the one (namely, the exposure machine for the array substrate) that forms the layer structure, such as the source and the drain, in the COA substrate, i.e., the black matrix with the thickness ranging from 2000 Å to 4000 Å can be formed by treating the metal film with the exposure apparatus and etching apparatus that are identical with those for forming the layer structure, such as the source and the drain, in the COA substrate. The material of the black matrix can be selected from at least one of the group consisting of molybdenum, chromium, aluminum, titanium and copper or an alloy containing at least one of the above metals or metal oxides and nitrides corresponding to any one of the above metals.

309. forming a common electrode layer on the black matrix.

To be specific, a layer of ITO or IZO with a thickness ranging from 300 Å to 500 Å is deposited by means of magnetron sputtering and then forms the common electrode layer after exposure, developing and etching.

310. making a second passivation layer that covers the substrate on the common electrode layer.

311. forming a pixel electrode layer on the second passivation layer.

What needs to be explained is that the steps of the flow-chart of the present embodiment that are identical with those in the previous embodiments will not be repeated herein.

As to the method for manufacturing the COA substrate according to the embodiment of the present disclosure, the metal material is used to form the black matrix in the COA substrate, and the black matrix made of the metal material replaces the black matrix made of carbon black particles in the prior-art technical solutions, such that it is effective to avoid the augmentation of the parasitic capacitance between the common electrode and the gate line and/or the common electrode and the data line due to the presence of the black matrix made of carbon black particles, which solves the problem of a greater parasitic capacitance generated between the common electrode and the gate line and/or the common electrode and the data line in the prior-art technical solutions, avoids signal delay, guarantees normal signal transmission and improves screen display quality of the display means.

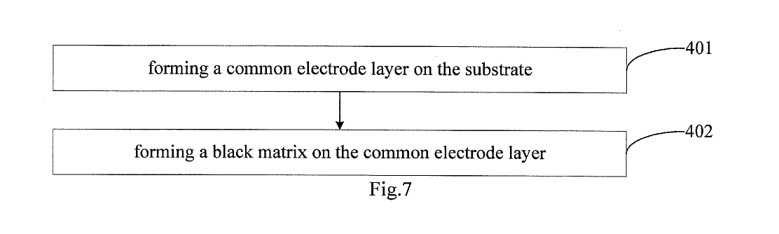

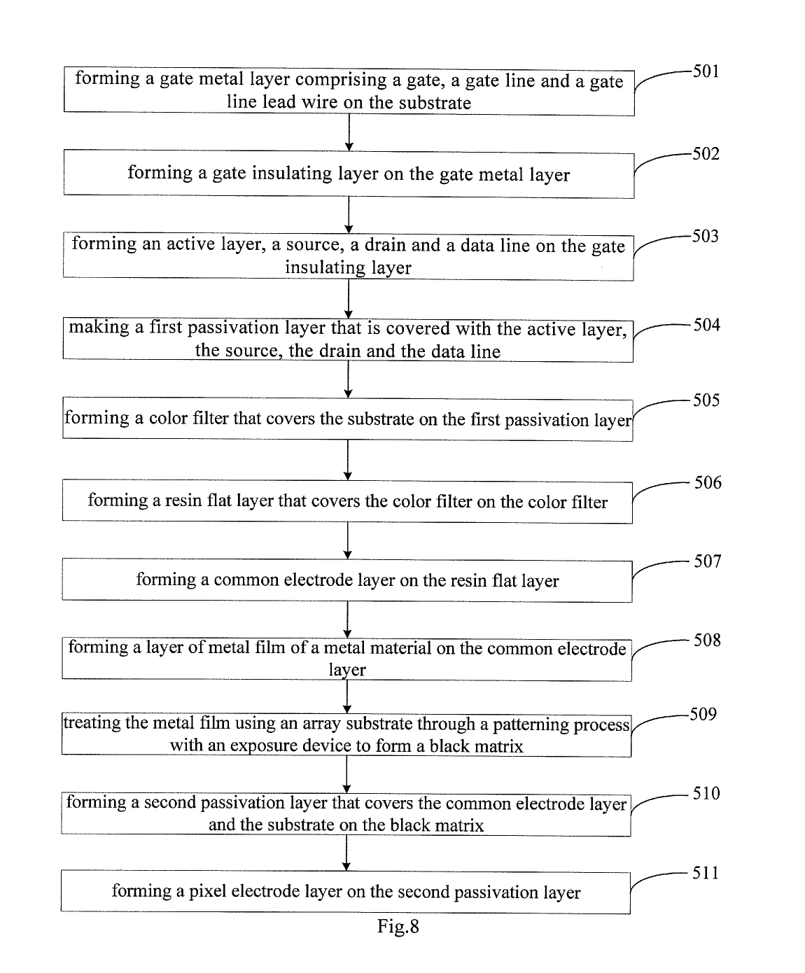

The embodiment of the present disclosure provides a method for manufacturing a COA substrate. With reference to FIG. 7, the method comprises the following steps:

401. forming a common electrode layer on the substrate.

To be specific, a layer of ITO or IZO with a thickness ranging from 300 Å to 500 Å is deposited by means of magnetron sputtering and then forms the common electrode layer after exposure, developing and etching.

402. forming a black matrix on the common electrode layer.

The black matrix is formed in a position of the common electrode layer where the normal shading effect of the black matrix is guaranteed.

As to the method for manufacturing the COA substrate according to the embodiment of the present disclosure, the black matrix in the COA substrate is made on the common electrode layer to ensure that the black matrix will never occur between the common electrode and the gate line and/or the common electrode and the data line, such that it is effective to avoid the augmentation of the parasitic capacitance between the common electrode and the gate line and/or the common electrode and the data line due to the presence of the black matrix, which solves the problem of a greater parasitic capacitance generated between the common electrode and the gate line and/or the common electrode and the data line in the prior-art technical solutions, avoids signal delay, guarantees normal signal transmission and improves screen display quality of the display means.

The embodiment of the present disclosure provides a method for manufacturing a COA substrate. With reference to FIG. 8, the method comprises the following steps:

501. forming a gate metal layer comprising a gate, a gate line and a gate line lead wire on the substrate.

502. forming a gate insulating layer on the gate metal layer.

503. forming an active layer, a source, a drain and a data line on the gate insulating layer.

504. making a first passivation layer that is covered with the active layer, the source, the drain and the data line.

505. forming a color filter that covers the substrate on the first passivation layer.

506. forming a flat layer that covers the color filter on the color filter.

507. forming a common electrode layer on the flat layer.

508. forming a layer of metal film from a metal material on the common electrode layer.

509. treating the metal film using an array substrate through a patterning process with an exposure apparatus to form a black matrix.

To be specific, the black matrix with the thickness ranging from 2000 Å to 4000 Å can be formed by treating the metal film with the exposure apparatus (namely, an exposure machine for the array substrate) and etching apparatus that are identical with those for forming the layer structure, such as the source and the drain, in the COA substrate. The material of the black matrix can be selected from at least one of the group consisting of molybdenum, chromium, aluminum, titanium and copper or an alloy containing at least one of the above metals or metal oxides and nitrides corresponding to any one of the above metals.

510. forming a second passivation layer that covers the common electrode layer and the substrate on the black matrix.

511. forming a pixel electrode layer on the second passivation layer.

What needs to be explained is that the steps of the flow-chart of the present embodiment that are identical with those in the previous embodiments will not be repeated herein.

As to the method for manufacturing the COA substrate according to the embodiment of the present disclosure, the black matrix in the COA substrate is made on the common electrode layer to ensure that the black matrix will never occur between the common electrode and the gate line and/or the common electrode and the data line, such that it is effective to avoid the augmentation of the parasitic capacitance between the common electrode and the gate line and/or the common electrode and the data line due to the presence of the black matrix, which solves the problem of a greater parasitic capacitance generated between the common electrode and the gate line and/or the common electrode and the data line in the prior-art technical solutions, avoids signal delay, guarantees normal signal transmission and improves screen display quality of the display means.

One embodiment of the present disclosure discloses a display device comprising any COA substrate according to the embodiments corresponding to FIGS. 1 and 2 of the present disclosure.

As to the display device according to the embodiment of the present disclosure, the metal material is used to form the black matrix in the COA substrate, and the black matrix made of the metal material replaces the black matrix made of carbon black particles in the prior-art technical solutions, such that it is effective to avoid the augmentation of the parasitic capacitance between the common electrode and the gate line and/or the common electrode and the data line due to the presence of the black matrix made of carbon black particles, which solves the problem of a greater parasitic capacitance generated between the common electrode and the gate line and/or the common electrode and the data line in the prior-art technical solutions, avoids signal delay, guarantees normal signal transmission and improves screen display quality of the display means.

One embodiment of the present disclosure discloses a display device comprising any COA substrate according to the embodiment corresponding to FIG. 3 of the present disclosure.

As to the display device according to the embodiment of the present disclosure, the black matrix in the COA substrate of the display device is made on the common electrode layer to ensure that the black matrix will never occur between the common electrode and the gate line and/or the common electrode and the data line, such that it is effective to avoid the augmentation of the parasitic capacitance between the common electrode and the gate line and/or the common electrode and the data line due to the presence of the black matrix, which solves the problem of a greater parasitic capacitance generated between the common electrode and the gate line and/or the common electrode and the data line in the prior-art technical solutions, avoids signal delay, guarantees normal signal transmission and improves screen display quality of the display means.

The above description is only related to the embodiments of the present disclosure; however, the protection scope of the present disclosure is not limited thereto. Any skilled person in the art can readily conceive of various modifications or variants within the technical scope of the present disclosure. Hence, the protection scope of the present disclosure shall be based on that of the appending claims.

1-20. (canceled)

21. A color filter on array substrate comprising:
a substrate;
a gate line;
a data line;
a common electrode layer; and
a black matrix formed of a metal material;
wherein the black matrix is arranged between the common electrode layer and at least one of the gate line and the data line.

22. The color filter on array substrate according to claim 21, wherein the black matrix is arranged adjacent to the common electrode layer.

23. The color filter on array substrate according to claim 21, comprising:
a flat layer; and
a color filter;
wherein the color filter is formed on the black matrix and covers the substrate; and
wherein the flat layer covers the color filter.

24. The color filter on array substrate according to claim 22, comprising:
a flat layer; and
a color filter;
wherein the color filter is formed on the black matrix and covers the substrate; and
wherein the flat layer covers the color filter.

25. The color filter on array substrate according to claim 21, wherein the metal material of the black matrix comprises at least one of molybdenum, chromium, aluminum, titanium, copper, an oxide of molybdenum, an oxide of chromium, an oxide of aluminum, an oxide of titanium, an oxide of copper, a nitride of molybdenum, a nitride of chromium, a nitride of aluminum, a nitride of titanium, and a nitride of copper.

26. The color filter on array substrate according to claim 21, wherein the black matrix has a thickness of about 0.2 to 0.4 μm.

27. A color filter on array substrate comprising:
a substrate;
a common electrode layer arranged on the substrate; and
a black matrix;
wherein the black matrix is arranged on the common electrode layer.

28. The color filter on array substrate according to claim 27, wherein the black matrix is formed of a metal material.

29. The color filter on array substrate according to claim 28, wherein the metal material of the black matrix comprises at least one of molybdenum, chromium, aluminum, titanium, copper, an oxide of molybdenum, an oxide of chromium, an oxide of aluminum, an oxide of titanium, an oxide of copper, a nitride of molybdenum, a nitride of chromium, a nitride of aluminum, a nitride of titanium, and a nitride of copper.

30. The color filter on array substrate according to claim 28, wherein the black matrix has a thickness of about 0.2 to 0.4 μm.

31. The color filter on array substrate according to claim 29, wherein the black matrix has a thickness of about 0.2 to 0.4 μm.

32. A display device comprising:
a frame;
a display panel; and
a color filter on array substrate comprising:
a substrate;
a gate line;
a data line;
a common electrode layer; and
a black matrix formed of a metal material;
wherein the black matrix is arranged between the common electrode layer and at least one of the gate line and the data line.

33. The display device according to claim 32, wherein the black matrix is arranged adjacent to the common electrode layer.

34. The display device according to claim 32, comprising:
a flat layer; and
a color filter;
wherein the color filter is formed on the black matrix and covers the substrate; and
wherein the flat layer covers the color filter.

35. The display device according to claim 33, comprising:
a flat layer; and
a color filter;
wherein the color filter is formed on the black matrix and covers the substrate; and
wherein the flat layer covers the color filter.

36. The display device according to claim 32, wherein the metal material of the black matrix comprises at least one of molybdenum, chromium, aluminum, titanium, copper, an oxide of molybdenum, an oxide of chromium, an oxide of aluminum, an oxide of titanium, an oxide of copper, a nitride of molybdenum, a nitride of chromium, a nitride of aluminum, a nitride of titanium, and a nitride of copper.

37. The display device according to claim 32, wherein the black matrix has a thickness of about 0.2 to 0.4 μm.
